(19) United States
(12) Patent Application Publication
(10) Pub. No.: US 2009/0073786 A1
(43) Pub. Date: Mar. 19, 2009

(54) EARLY WRITE WITH DATA MASKING TECHNIQUE FOR INTEGRATED CIRCUIT DYNAMIC RANDOM ACCESS MEMORY (DRAM) DEVICES AND THOSE INCORPORATING EMBEDDED DRAM

(75) Inventors: Michael C. Parris, Colorado Springs, CO (US); Kim C. Hardee, Colorado Springs, CO (US)

Correspondence Address: HOGAN & HARTSON LLP, ONE TABOR CENTER, SUITE 1500, 1200 SEVENTEENTH ST, DENVER, CO, 80202, US

(73) Assignees: UNITED MEMORIES, INC., Colorado Springs, CO (US); SONY CORPORATION, Tokyo (JP)

(21) Appl. No.: 11/855,804

(22) Filed: Sep. 14, 2007

(51) Int. Cl. G11C 7/00

(52) U.S. Cl. 365/190

(57) ABSTRACT

An early write with data masking technique for dynamic random access memory (DRAM) devices and those devices incorporating embedded DRAM. The technique of the present invention allows for early writes to DRAM arrays with direct bit, byte or word data masking capability.

### BACKGROUND OF THE INVENTION

The present invention relates, in general, to the field of integrated circuit memory devices. More particularly, the present invention relates to an early write (EW) with data masking technique for dynamic random access memory (DRAM) devices and those devices incorporating embedded DRAM.

Early write techniques have previously been described in conjunction with DRAM devices to improve memory cell restore times and overall write cycle times. An early write operation generally consists of writing new data to the bitlines before the column sense amplifiers have been activated. This results in faster memory cell voltage restore times since non-early writes, or traditional DRAM writes, occur after the sense amplifier has been activated. This traditional, or late, DRAM write is slower to restore cell node voltage levels since the sense amplifier starts to amplify old data, then needs to be overpowered by the write circuitry, whereupon new data is restored into the memory cell.

A problem with conventional early write designs is that they are unable to mask data in a traditional way. Data masking during a write operation is employed when a data stream is directed to a memory cell array but it is also desired that certain data already stored in the array remain unchanged. In operation, a data mask is then utilized to block some of the data from reaching these specific memory locations.

Late write designs can mask data by bit, byte or word by holding the internal data lines at a double high (data “D” and data complement “/D” pair) which prevents the sense amplifier from flipping and new data being written. However as previously mentioned, none of the known circuits and methods for implementing early write operations allow for industry standard data masking.

U.S. Pat. No. 6,504,766 issued Jan. 7, 2003 for: “System and Method for Early Write to Memory by Injecting Small Voltage Signal” describes a technique implemented through the injection of a small voltage differential signal prior to setting a sense amplifier and thereafter setting the sense amplifier to amplify the small voltage signal to predetermined high and low voltage logic levels for writing to the memory cell. This small signal is injected after the wordline goes “high” but before the latch p-channel bar (LPB) and latch n-channel bar (LNB) nodes fire.

U.S. Pat. No. 6,788,591 issued Sep. 7, 2004 for: “System and Method for Direct Write to Dynamic Random Access Memory (DRAM) using PFET Bit-Switch” describes a technique wherein a write operation to a selected cell is commenced prior to the completion of the time associated with signal development on the true/complementary bitlines of the memory array. The technique described, while effectuating writes before the wordlines go “high” does not accomplish, or allow for, data masking and creates disturbs while consuming more power since the bitlines and local write lines transition to full power supply (VCC) levels.

### SUMMARY OF THE INVENTION

Disclosed herein is an early write with data masking technique for dynamic random access memory (DRAM) devices and those devices incorporating embedded DRAM. The technique of the present invention allows for early writes to DRAM arrays with direct bit, byte or word data masking capability.

Particularly disclosed herein is a technique for writing data to a memory array having at least one pair of complementary bitlines, at least one pair of complementary data lines and at least one wordline, with the memory array further comprising associated column write clock and sense amplifier enable signals. The technique comprises the steps of: asserting the column write clock; writing data to the complementary bitlines; applying a predetermined signal level to the complementary data lines; activating the wordline and activating the sense amplifier enable signal.

In a particular implementation of the technique of the present invention, the technique further comprises the step of: maintaining a same voltage on the complementary data lines to mask certain of the data to be written to the complementary bitlines.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1 is a simplified schematic and functional block diagram of a circuit for possible implementation of the technique of the present invention;

FIG. 2 is a grouping of waveforms indicative of a conventional early write operation and showing the interrelationship and relative timing among them;

FIG. 3 is an additional grouping of the same waveforms indicative of a conventional late write operation and showing the interrelationship and relative timing among them;

FIG. 4 is a representative grouping of waveforms indicative of an early write operation in accordance with the technique of the present invention and showing the interrelationship and relative timing among them; and

FIG. 5 is another representative grouping of the same waveforms indicative of a data masking operation in accordance with the technique of the present invention and showing the interrelationship and relative timing among them.

### DESCRIPTION OF A REPRESENTATIVE EMBODIMENT

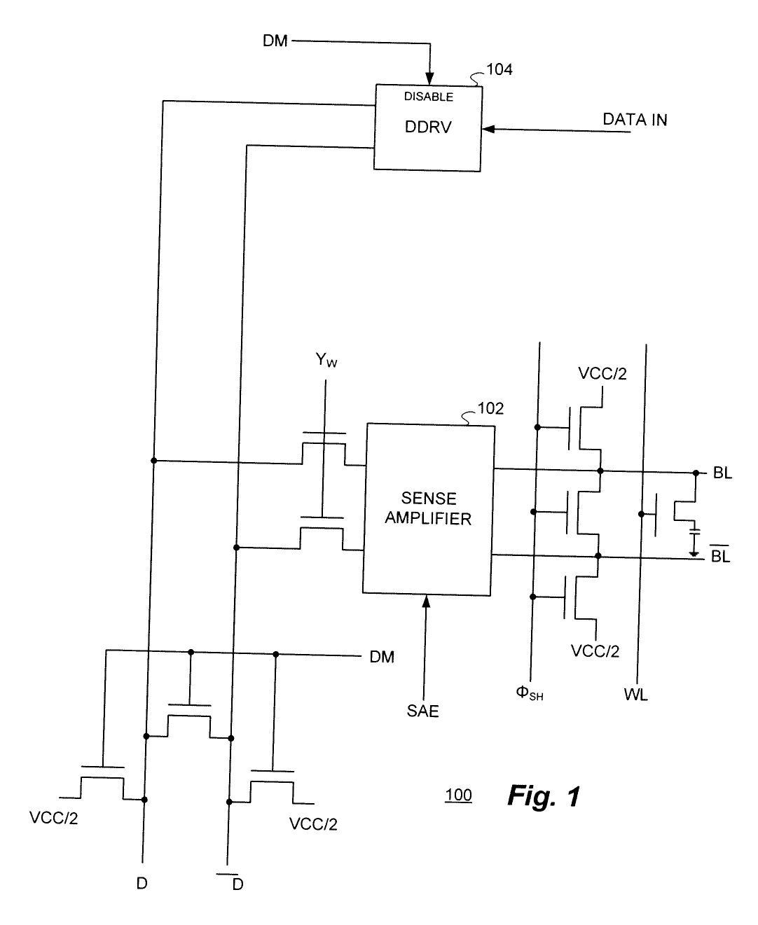

With reference now to FIG. 1, a simplified schematic and functional block diagram of a circuit 100 for possible implementation of the technique of the present invention is shown. The circuit 100 comprises, in pertinent part, a sense amplifier 102 and data drive (DDRV) circuit 104. In operation as will be more fully described hereinafter, the data mask (DM) signal disables the data lines (D, /D) or the DDRV circuit 104.

As illustrated, the pertinent inputs to the circuit 100 also include the shorting clock signal (φ_{SH}), the column write clock (Y_{w}), the wordline (WL), the complementary internal data lines (D, /D), the complementary bitlines (BL, /BL) and the sense amplifier enable signal (SAE).

By way of background, in a conventional read operation, first the shorting clock signal transitions from a logic “low” to logic “high” and back followed by the assertion of the wordline which couples the associated memory cells to their respective bitlines. The sense amplifier enable signal is then asserted in conjunction with the column read clock to read the stored data from the selected column of memory cells. The complementary data lines are shorted together to VCC/2 (one half the supply voltage) for a portion of the read cycle in order to precharge the data lines in preparation of transferring signal from the sense amplifier. This read cycle is described for purposes of comparison only and is generally representative of a read operation whether or not used in conjunction with a conventional early (or late) write operation or the technique of the present invention.

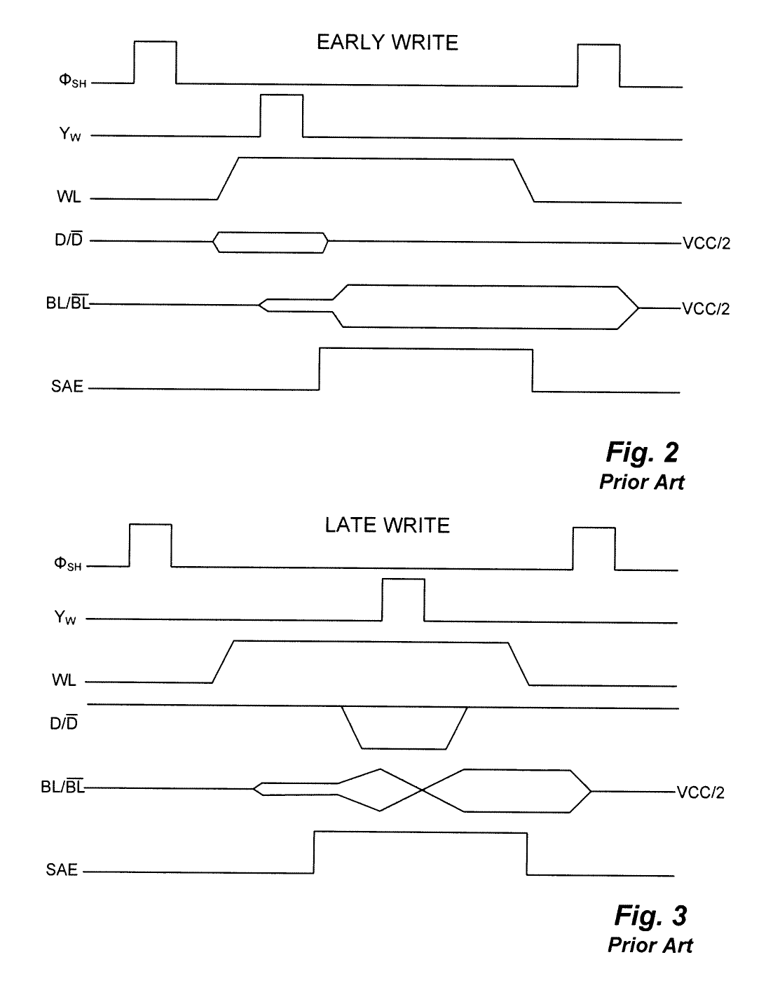

With reference additionally now to FIG. 2, a grouping of the waveforms is shown indicative of a conventional early write operation and illustrating the interrelationship and relative timing among them.

In this example, the shorting clock signal transitions from a logic “low” to logic “high” and back followed by the assertion of the wordline which again couples the associated memory cells to their respective bitlines. The column write clock then transitions and the sense amplifier enable signal is asserted to write the input data to the selected column of memory cells. It should be noted that with this timing, its is not possible to short the complementary data lines D and /D to VCC/2 to mask data because, in so doing, such a masking operation would also short out actual memory cell data causing that data to be corrupted or lost.

With reference additionally now to FIG. 3, an additional grouping of the same waveforms is shown indicative of a conventional late write operation and illustrating the interrelationship and relative timing among them. A late write operation is the conventional approach used in traditional DRAM array write operations and it can be seen that the write clock signal occurs some time after the assertion of the wordline signal unlike the conventional early write operation of the preceding figure.

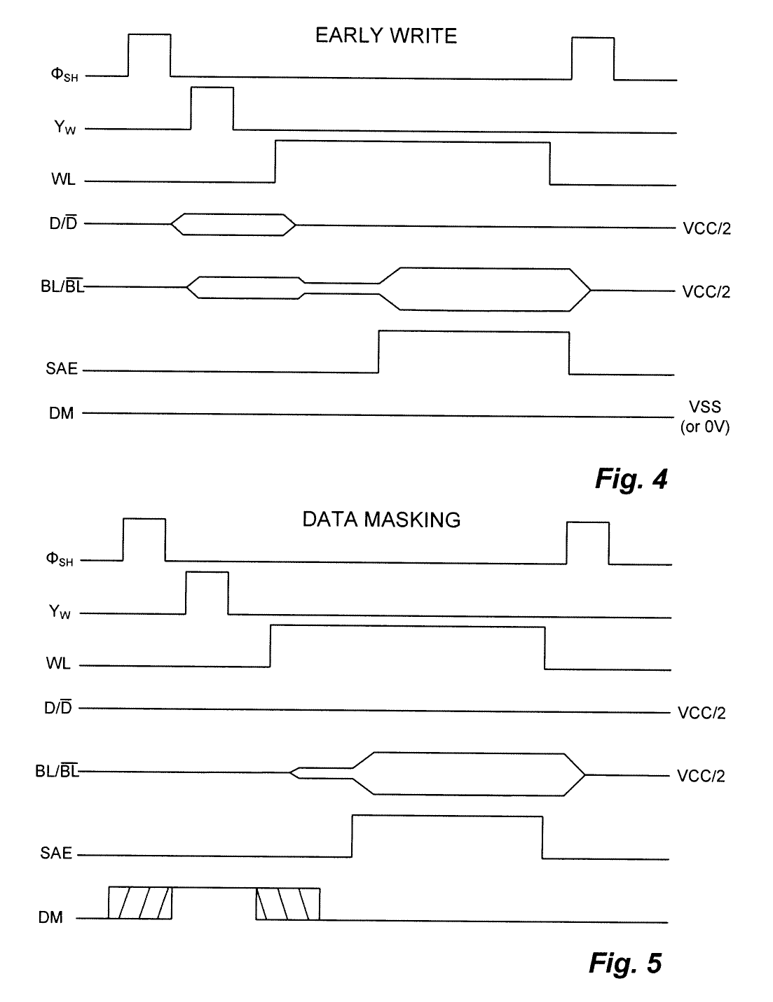

With reference additionally now to FIG. 4, a representative grouping of waveforms is shown indicative of an early write operation in accordance with the technique of the present invention and illustrating the interrelationship and relative timing among them. In accordance with the technique of the present invention, data can be written to the bitlines before the wordline is activated, after the ASH, or shorting clock turns “off”.

At this point, a small signal level is used on the complementary data lines D and /D to minimize any possible disturbance to surrounding bitlines. However, it is sufficiently large to maintain this data after the wordline goes “high” and old, opposite, data comes out of the memory cell. In operation, there is still enough of the new signal to sense when the sense amplifier enable signal goes “high”. The data masking (DM) signal is at VSS or 0 volts for the entire operation.

With reference additionally now to FIG. 5, another representative grouping of the same waveforms is shown indicative of a data masking operation in accordance with the technique of the present invention and illustrating the interrelationship and relative timing among them. This figure is similar to the preceding FIG. 4 early write operation and it can be seen that in order to mask the complementary internal data lines D and /D, they can be held to VCC/2, or the same voltage as the bitline precharge level. The DM signal transitions to a “high” state before the column write clock (Y_{w}) and remains “high” after Y_{w}. Otherwise, the timing of DM is not critical to the technique of the present invention.

While there have been described above the principles of the present invention in conjunction with specific operational characteristics, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

As used herein, the terms “comprises”, “comprising”, or any other variation thereof, are intended to cover a non-exclusive inclusion, such that a process, method, article, or apparatus that comprises a recitation of certain elements does not necessarily include only those elements but may include other elements not expressly recited or inherent to such process, method, article or apparatus. None of the description in the present application should be read as implying that any particular element, step, or function is an essential element which must be included in the claim scope and THE SCOPE OF THE PATENTED SUBJECT MATTER IS DEFINED ONLY BY THE CLAIMS AS ALLOWED. Moreover, none of the appended claims are intended to invoke paragraph six of 35 U.S.C. Sect. 112 unless the exact phrase “means for” is employed and is followed by a participle.

What is claimed is:

1. A technique for writing data to a memory array having at least one pair of complementary bitlines, at least one pair of complementary data lines and at least one wordline, said memory array further comprising associated column write clock and sense amplifier enable signal, said technique comprising:
applying predetermined signal levels to said complementary data lines;
asserting said column write clock;
writing complementary data to said complementary bitlines;
activating said wordline; and
activating said sense amplifier enable signal.

2. The technique of claim 1 further comprising:
deasserting a shorting clock signal prior to asserting said column write clock.

3. The technique of claim 1 wherein said predetermined signal level is of a level sufficiently high to maintain said data following said activation of said wordline.

4. The technique of claim 3 wherein said predetermined signal level is also of a level sufficiently low to minimize disturbances to other adjacent complementary bitlines of said memory array.

5. The technique of claim 2 further comprising:
deactivating said wordline and said sense amplifier enable signal prior to reassertion of said shorting clock signal.

6. The technique of claim 1 further comprising:
masking certain of said data to be written to said complementary bitlines.

7. The technique of claim 6 wherein said step of masking comprises:
maintaining a same voltage level on said complementary data lines.

8. The technique of claim 7 wherein said same voltage level is substantially a precharge level of said complementary bitlines.

9. The technique of claim 7 wherein said same voltage level is substantially one half of a supply voltage level.

10. An integrated circuit device incorporating a memory array having at least one pair of complementary bitlines, at least one pair of complementary data lines and at least one wordline, said memory array further comprising associated column write clock and sense amplifier enable signal, said integrated circuit device comprising:
means for applying predetermined signal levels to said complementary data lines;
means for asserting said column write clock;
means for writing data to said complementary bitlines;
means for activating said wordline; and
means for activating said sense amplifier enable signal.

11. The device of claim 10 further comprising:
means for deasserting a shorting clock signal prior to asserting said column write clock.

12. The device of claim 10 wherein said predetermined signal level is of a level sufficiently high to maintain said data following said activation of said wordline.

13. The device of claim 12 wherein said predetermined signal level is also of a level sufficiently low to minimize disturbances to other adjacent complementary bitlines of said memory array.

14. The device of claim 11 further comprising:
means for deactivating said wordline and said sense amplifier enable signal prior to reassertion of said shorting clock signal.

15. The device of claim 10 further comprising:
means for masking certain of said data to be written to said complementary bitlines.

16. The device of claim 15 wherein said means for masking comprises:
means for maintaining a same voltage level on said complementary data lines.

17. The device of claim 16 wherein said same voltage level is substantially a precharge level of said complementary bitlines.

18. The device of claim 16 wherein said same voltage level is substantially one half of a supply voltage level.
